(19) United States
(12) Patent Application Publication
(10) Pub. No.: US 2025/0076773 A1
(43) Pub. Date: Mar. 6, 2025

(54) HANDLING SYSTEM FOR MICROLITHOGRAPHIC PHOTOMASKS, INSPECTION SYSTEM AND PROCESSING SYSTEM HAVING A HANDLING SYSTEM

(71) Applicant: Carl Zeiss SMT GmbH, Oberkochen (DE)

(72) Inventor: Johann Irnstetter, Heidenheim an der Brenz (DE)

(21) Appl. No.: 18/816,180

(22) Filed: Aug. 27, 2024

(30) Foreign Application Priority Data
Aug. 28, 2023 (DE) 102023123098.0

(51) Int. Cl. G03F 7/00; G03F 1/84

(52) U.S. Cl. CPC G03F 7/70741; G03F 1/84

(57) ABSTRACT

The invention relates to a handling system for microlithographic photomasks, having an articulated arm robot and having an alignment device. The alignment device is designed to rotate a photomask held by the alignment device about a vertical axis during a first movement process and flip said photomask about a horizontal axis during a second movement process. The invention also relates to an inspection system having a handling system and to a processing system having a handling system.

### CROSS-REFERENCE TO RELATED APPLICATION

The present application claims the priority of the German patent application DE 10 2023 123 098.0, filed on Aug. 28, 2023, the entire contents of which are incorporated herein by reference.

### TECHNICAL FIELD

The invention relates to a handling system for microlithographic photomasks. The invention also relates to a processing system having a handling system and to an inspection system having a handling system.

### BACKGROUND

Photomasks are used in microlithographic projection exposure apparatuses, which are used to produce integrated circuits with particularly small structures. The photomask illuminated by very short-wavelength deep ultraviolet or extreme ultraviolet radiation (DUV or EUV radiation) is imaged onto a lithography object in order to transfer the mask structure to the lithography object.

To ensure a high quality of the image created on the lithography object, it is necessary for the photomask to be true to size and not adversely affected by contamination. It is for this reason that photomasks can be subjected to an inspection and can be post-processed, cleaned or corrected where necessary, either prior to the first use or within the scope of servicing measures. In this context, use is made of different inspection systems and processing systems, to which the photomasks are transferred for the purpose of carrying out the necessary steps. The steps in the inspection systems and processing systems are regularly carried out in vacuo.

For example, contamination may be caused by an outgassing of components in the surroundings of photomasks; this leads to the contamination being deposited on the surface of the photomask. This is especially problematic in those regions of the photomask in which the structures for the subsequent chips are arranged. A contamination risk can also arise from foreign particles, which for example originate from the contact points of the mask. These frequently consist of plastic and therefore have a relatively high outgassing rate. Plastics particles can decompose to form carbon under the influence of UV light, and this may lead to a degradation of the reflectivity of the photomask and of optical components.

It is necessary to ensure that a photomask is correctly aligned before said photomask is introduced into an inspection system/processing system. To this end, the photomask is rotated about a vertical axis and/or flipped about a horizontal axis, depending on the initial state. The movement process used to introduce the photomask into the inspection system or processing system only follows then.

The use of six-axis robots, which have all required degrees of freedom of movement, for movement processes comprising a translation and an alignment of photomasks is known. However, the spatial conditions in the surroundings of inspection systems and processing systems are frequently cramped, and so the space available is insufficient for six-axis robots. In particular, the installation height of the components carrying the photomask is frequently so large that it is not possible to deposit the photomask under cramped spatial conditions.

Complex systems in which different system components are used for different parts of the movement process are also known. For example, a first system component can be responsible for translational movements in a horizontal plane, a second system component can be responsible for a rotation about a vertical axis and a third system component can be responsible for flipping the photomask about a horizontal axis. The invention is based on the aspect of presenting a handling system, an inspection system and a processing system which avoid these disadvantages. The aspect is achieved by the features of the independent claims. Advantageous embodiments are specified in the dependent claims.

### SUMMARY

A handling system according to the invention for microlithographic photomasks comprises an articulated arm robot and an alignment apparatus. The alignment device is designed to rotate a photomask held by the alignment device about a vertical axis during a first movement process and flip said photomask about a horizontal axis during a second movement process. Specifying a first movement process and a second movement process is not linked with any restrictions with regard to the temporal sequence of the movement processes.

The invention has recognized that this allows the complexity to be reduced vis-à-vis known systems. With regard to the types of joints required for the handling system according to the invention, it is easier to design the joints such that outgassing is avoided should photomasks be handled under vacuum conditions.

The articulated arm robot can comprise a robot base, a first articulated arm attached to the robot base by way of a first revolute joint, a second articulated arm attached to the first articulated arm by way of a second revolute joint and a third articulated arm attached to the second articulated arm by way of a third revolute joint.

A revolute joint refers to a joint providing a rotation about exactly one axis. This restriction to one degree of freedom of movement allows simple encapsulation of the joint; this is advantageous with regard to avoiding outgassing. One or more revolute joints may have a vacuum-tight encapsulation such that particles arising within the revolute joint are prevented from passing into the surroundings. The axes of the first revolute joint, second revolute joint and third revolute joint of the articulated arm robot can be aligned in parallel with one another such that a distal end of the third articulated arm can be moved in an XY-plane by actuating the revolute joints. The XY-plane can be a horizontal plane.

Each of the revolute joints can be provided with a joint drive such that actuation of the joint drive can change the position of the revolute joint. The joint drive may be embodied as a rotary drive motor. Each joint drive may be an element of the respective revolute joint. The joint drives can be controlled by way of control signals. The first revolute joint may comprise a first rotary drive, a first connector connected to the robot base and a second connector connected the first articulated arm. The second revolute joint may comprise a second rotary drive, a third connector connected to the first articulated arm and a second connector connected the second articulated arm. The third revolute joint may comprise a third rotary drive, a fifth connector connected to the second articulated arm and a sixth connector connected the third articulated arm.

The articulated arm robot may comprise a linear drive in order to be able to modify the height position of the third articulated arm in the Z-direction. The linear drive can be arranged between the robot base and the first articulated arm. A change in the height position of the first articulated arm at the same time also changes the height position of the second articulated arm carried by way of the first articulated arm. The linear drive is also restricted to one degree of freedom of movement; this is advantageous with regard to avoiding outgassing. The linear drive can be provided with a vacuum-tight encapsulation in order to prevent the emergence of particles arising due to friction.

The alignment device can comprise a holding mechanism for a photomask. The holding mechanism can be designed such that the photomask is held in the holding mechanism independently of the alignment with respect to gravity. In an embodiment, the holding mechanism comprises a first clamping jaw and a second clamping jaw. The holding mechanism may comprise an actuator so that the distance between the first clamping jaw and the second clamping jaw can be set. In a first state of the holding mechanism, the distance between the clamping jaws can be greater than the distance between two opposite ends of the photomask to be held. In a second state of the holding mechanism, the clamping jaws can abut against the two ends of the photomask such that the photomask is held between the clamping jaws.

The holding mechanism may have an initial position in which the holding mechanism is designed to grip and lift a photomask lying on a structure. The photomask lying on the structure may be aligned horizontally. The holding device can engage on two opposite edges of the photomask in order to lift said photomask.

Inspection systems and processing systems are frequently designed such that a photomask must be introduced in a defined alignment. Should a photomask having approximately the shape of a rectangle be assumed, there are four positions, rotated through 90°, in which the edges of the photomask are aligned parallel to the X-direction and parallel to the Y-direction. A rotation of the photomask about the Z-axis might be required in order to bring the photomask into the correct one of the four possible rotary positions.

The correct alignment also includes the correct face of the photomask pointing upwards. Should the photomask lie on the structure with the wrong alignment, the photomask must be flipped through 180° about a horizontal axis in order to bring it into the correct alignment. Hence there are a total of eight different possibilities with regard to how a photomask held in the holding mechanism might be aligned.

The handling system might comprise a sensor mechanism for capturing the alignment of the photomask. The photomask might be provided with markers that allow an identification of the alignment. For example, should one of four corners of the photomask be provided with a marker, this marker can allow unambiguous ascertainment as to the photomask's rotational positions from a possible four. Likewise, whether the photomask needs to be flipped can be ascertained on the basis of one marker. The sensor mechanism can be designed to capture the alignment of the photomask on the basis of such markers. For example, the sensor mechanism might comprise an optical sensor that reacts to the markers.

The sensor mechanism can be a constituent part of the alignment device. This is advantageous in that information about a photomask held in the alignment device can be obtained directly by way of the sensor mechanism.

The alignment device might comprise a first rotary drive for rotating the holding mechanism about the vertical axis. The vertical axis refers to an axis which makes a right angle with the photomask plane. The first rotary drive preferably has exactly one degree of freedom, specifically a rotational degree of freedom for a rotation about the axis. The first rotary drive can be provided with a vacuum-tight encapsulation. The first rotary drive might comprise four rotational positions which each differ from one another by 90°. Control commands used to appropriately control the first rotary drive can be stored in a control unit of the handling system. The control unit may comprise a memory element for storing control information from which control commands may be derived. The control unit may comprise a calculator module for deriving control commands from the control information. The control unit may comprise a command module configured to send control commands to components of the handling system. The first rotary drive might be equipped with a fine adjustment means, by means of which the various rotary positions can be preset with great accuracy. The alignment device can then be adjusted directly by way of the drive axis rather than by way of a fine mechanical adjustment. The axis of the first rotary drive might make a right angle with a plane spanned by a photomask held in the holding mechanism. The axis of the first rotary drive can intersect the photomask centrally, with the result that the photomask is in equilibrium relative to the axis. This is advantageous in that a small torque of the first rotary drive suffices for rotating the holding mechanism with the photomask held therein.

The first rotary drive can comprise a motor having a rotor and a stator. The motor can be a stepper motor. The stator can be held on a structure of the alignment device. The first rotary drive can comprise an encoder which supplies information about the rotary position of the motor. The first rotary drive forms an actuator of the handling system with a single degree of freedom of movement.

There can be direct coupling between the rotor and the holding mechanism or a structure component of the alignment device holding the holding mechanism, with the result that the holding mechanism rotates directly with the rotor. If the motor axis of the first rotary drive is aligned in parallel with the vertical axis about which the photomask is rotated, then a small axial dimension of the motor is advantageous with regard to a low installation height. In general, a small axial extent can be achieved better with an external-rotor motor than with an internal-rotor motor. A larger diameter of the motor is acceptable in exchange.

A gearing might also be arranged between the motor of the first rotary drive and the holding mechanism. The motor axis can then have a different alignment to the axis about which the holding mechanism is rotated. For example, there might be an angle of 90° between the two axes. Should the motor axis be aligned horizontally, an internal-rotor motor enabling a smaller diameter than an external-rotor motor might be advantageous.

A small installation height is a specific requirement of the photomask handling according to the invention. Depositing the photomask within a space or guiding it through an opening which is upwardly and downwardly delimited by adjacent structures is only possible if the requirement of a low installation height is met. The only space available allowing the introduction of the photomask into the space and its deposition there is the space between the adjacent structures. The holding mechanism may comprise a frame bracket, attached to which are two gripping elements which are designed when coming from a lateral direction to grip the photomask arranged in a horizontal plane. To this end, the frame bracket having the gripping elements may have a horizontal extent greater than the extent of the photomask in the relevant direction. The directional specifications regarding the definition of the installation height relate to this alignment of the photomask and the holding mechanism.

A small vertical distance between the photomask and the frame bracket is advantageous for a low installation height. The vertical distance between the photomask and the frame bracket can be less than 6 mm, preferably less than 2 mm, and further preferably less than 1 mm. The specification relates to the greatest clear space between the photomask and the frame bracket in the vertical direction.

A small installation height of the frame bracket is advantageous. For example, the installation height of the frame bracket can be less than 12 mm, preferably less than 8 mm, and further preferably less than 6 mm. The specification relates to a portion of the frame bracket that does not protrude beyond the photomask in the lateral direction.

The frame bracket having the gripping elements can be designed such that the photomask can be held independently of the alignment with respect to gravity of the unit made of frame bracket, gripping elements and photomask. To this end, it is generally necessary to grip around the photomask such that the gripping elements encompass a portion which protrudes beyond the photomask on the side facing away from the frame bracket. The portion of the gripping elements protruding beyond the photomask might have a vertical extent of no more than 3 mm, and preferably of no more than 2 mm. If these vertical extents of the gripping elements differ, then the specification relates to the gripping element with the greatest extent. The gripping elements may have a surface with significant static friction in the region where they abut against the photomask. For example, the surface might consist of polyetheretherketone (PEEK).

The first rotary drive might be arranged such that the frame bracket is disposed between the first rotary drive and the photomask in relation to the vertical direction. The installation height (e.g., 61 in FIG. 4) of the first rotary drive can be less than 40 mm, preferably less than 25 mm, and further preferably less than 10 mm.

In an alternative embodiment, a lower installation height is achieved by virtue of the first rotary drive being arranged in a position to the side of the photomask. This case requires a transfer of the rotary movement from the first rotary drive to a rotary movement of the photomask. This transfer can be implemented by way of a toothed belt or a metal belt, for example.

The installation height (e.g., 62 in FIG. 4) of the constituent parts of the handling system to be introduced into the constricted space may correspond to the greatest vertical extent from the gripping elements to the first rotary drive. In particular, a frame part attached to the first rotary drive might be fastened such that it does not protrude beyond the rotary drive in the vertical direction. The frame part can form a load-bearing connection between the photomask and an articulated arm of the articulated arm robot. The installation height of these constituent parts can be less than 100 mm, preferably less than 80 mm, further preferably less than 60 mm, and further preferably less than 40 mm. The installation height (e.g., 63 in FIG. 5) which includes the first rotary drive and extends as far as the closest face of the photomask can be less than 30 mm, preferably less than 20 mm, and further preferably less than 15 mm.

The alignment device might comprise a second rotary drive for flipping the holding mechanism about a horizontal axis. The horizontal axis denotes an axis aligned parallel to the plane of the photomask. The second rotary drive preferably has exactly one degree of freedom, specifically a rotational degree of freedom for a rotation about the axis. The second rotary drive can be provided with a vacuum-tight encapsulation. The second rotary drive can comprise a first rotary position and a second rotary position rotated through 180° in relation thereto. Control commands used to appropriately control the second rotary drive can be stored in a control unit of the handling system. The control unit may comprise a memory element for storing control information from which control commands may be derived. The control unit may comprise a calculator module for deriving control commands from the control information. The control unit may comprise a command module configured to send control commands to components of the handling system. The second rotary drive might be equipped with a fine adjustment means, by means of which the various rotary positions can be preset with great accuracy. The alignment device can then be adjusted directly by way of the drive axis rather than by way of a fine mechanical adjustment. The axis of the second rotary drive might be in a plane spanned by a photomask held in the holding mechanism. The axis of the second rotary drive can intersect the photomask centrally, with the result that the photomask is in equilibrium relative to the axis. This is advantageous in that a small torque of the second rotary drive suffices for flipping the holding mechanism with the photomask held therein.

The second rotary drive can comprise a motor having a rotor and a stator. The motor can be a stepper motor. The second rotary drive can comprise an encoder which supplies information about the rotary position of the motor. The stator can be held on a structure of the alignment device. There can be direct coupling between the rotor and the holding mechanism or a structure component of the alignment device holding the holding mechanism, with the result that the holding mechanism rotates directly with the rotor.

A small installation height of the alignment device is frequently desired. If the axis of the motor is parallel to the horizontal axis about which the photomask is rotated, then this contributes to a small installation height if the motor has a small diameter. In this case, the motor is advantageously an internal-rotor motor, which generally allows smaller diameters than external-rotor motors. A greater extent in the axial direction is acceptable in exchange.

A gearing might also be arranged between the motor of the second rotary drive and the holding mechanism. The motor axis can then have a different alignment to the axis about which the holding mechanism is turned. For example, there might be an angle of 90° between the two axes. Should the motor axis be aligned vertically, an external-rotor motor enabling smaller axial extents than an internal-rotor motor might be advantageous.

The first rotary drive can be held on a structure component of the alignment device that is flipped by the second rotary drive. Alternatively, the second rotary drive can be held on a structure component of the alignment device that is rotated with the first rotary drive.

The handling system might comprise a control unit designed to control the rotary drives of the alignment device and/or the joint drives of the revolute joints by way of control signals. The control unit may comprise a memory element for storing control information from which control commands may be derived. The control unit may comprise a calculator module for deriving control commands from the control information. The control unit may comprise a command module configured to send control commands to components of the handling system.

The articulated arm robot and the alignment device can be separate components of the handling system. The alignment device can be arranged at a stationary position such that the alignment device remains in an unchanged position relative to the robot base of the articulated arm robot should the articulated arm robot be actuated.

The third articulated arm of the articulated arm robot can be embodied as an end effector designed to take a photomask from the alignment device and/or transfer a photomask to the alignment device. The third articulated arm can be equipped with a bearing element on which a photomask carried by the third articulated arm rests. The articulated arm robot can be designed to transfer the photomask to the holding mechanism of the alignment device and to take the photomask back from the holding mechanism of the alignment device after the photomask received the correct alignment by the alignment device.

In order to transfer the photomask to the holding mechanism, the photomask can be displaced in the horizontal direction by the articulated arm robot until the photomask is arranged horizontally above or below the holding mechanism. The linear motor of the articulated arm robot can be used to drive the photomask upwardly or downwardly until it is at a height position at which it can be gripped by the holding mechanism. The third articulated arm can then be displaced to the side such that the alignment device can align the photomask without colliding with components of the articulated arm robot. The subsequent transfer from the holding mechanism to the articulated arm robot can be implemented accordingly. The articulated arm robot can subsequently transfer the photomask to the process chamber or to an antechamber of the process chamber of the inspection system or processing system.

In an alternative embodiment, the articulated arm robot and the alignment device are elements of a handling system designed as a single device. The alignment device can be attached to the third articulated arm of the articulated arm robot. Thus, the position of the alignment device changes together with the third articulated arm when the articulated arm robot is actuated.

An axis of rotation of the alignment device can be aligned in parallel with the longitudinal direction of the third articulated arm. This can be the axis of rotation of the second rotary drive used to flip the photomask through 180° .

The photomask can rest on a bearing station before it is taken by the holding mechanism of the handling system. The holding mechanism can be displaced in the horizontal direction together with the articulated arm robot of the handling system until the holding mechanism is in a position from where it is able to grip the photomask. Subsequently, the holding mechanism can be displaced upwardly by the linear drive of the articulated arm robot, in order to raise the photomask from the bearing station.

The alignment device can be actuated in order to bring the photomask into the correct alignment. The articulated arm robot can subsequently be actuated to transfer the photomask to a process chamber or to an antechamber of a process chamber of the inspection system or processing system. A bearing station on which the photomask is placed can be arranged in the process chamber or the antechamber of the process chamber. To this end, the holding mechanism is displaced with the photomask to a position above the bearing station by way of an actuation of the articulated arm robot, and then the linear drive of the articulated arm robot is actuated to displace the holding mechanism downwardly and place the photomask onto the bearing station.

The bearing station may have a self-centering effect such that a photomask placed on the bearing station is automatically brought into a central position relative to the bearing station. The bearing station may comprise wedge faces, along which the photomask slides when it is lowered onto the bearing station. The wedge faces can be designed such that a lateral edge of the photomask comes into contact with the wedge faces. The wedge faces may have a surface made of a material that promotes sliding. The wedge faces may have a centering effect in a horizontal direction. The bearing station may have a wedge face for each of the four lateral edges of the photomask. The bearing station may have two wedge faces for each of the four lateral edges of the photomask. The holding mechanism can be designed such that a frame bracket of the holding mechanism is positioned between two wedge faces arranged on a lateral edge of the photomask when a photomask is placed on the bearing station. The holding mechanism can be designed such that the gripping elements used to grip the photomask are positioned between two wedge faces arranged on a lateral edge of the photomask when a photomask is placed on the bearing station.

The bearing station can be designed such that a bearing structure can be displaced under the photomask from a lateral direction in each of the eight possible alignments of the photomask, with the result that the photomask can be placed on the bearing structure, and the photomask can be released from the holding mechanism of the alignment device. Subsequently, the support structure and the alignment device can be spatially separated from one another. The alignment device can be moved relative to the bearing structure for these steps, or the bearing structure can be moved relative to the alignment device.

The invention also relates to an inspection system for microlithographic photomasks, having a handling system according to the invention and having a process chamber for conducting an examination of a photomask. The handling system is designed to transfer the photomask to the process chamber or to an antechamber of the process chamber.

The invention also relates to a processing system for microlithographic photomasks, having a handling system according to the invention and having a process chamber for conducting a processing step on a photomask. The handling system is designed to transfer the photomask to the process chamber or to an antechamber of the process chamber.

### BRIEF DESCRIPTION OF DRAWINGS

The invention will be described by way of example below on the basis of advantageous embodiments by reference to the accompanying drawings. In the drawings:

FIG. 1: shows an example of an inspection system according to the invention;

FIG. 2: shows an embodiment of a handling system according to the invention;

FIG. 3: shows the handling system from FIG. 2 in a different view;

FIG. 4: shows components of the handling system from FIGS. 2 and 3;

FIG. 5: shows the view according to FIG. 4 in another state of the handling system;

FIG. 6: shows a photomask on a bearing station;

FIG. 7: shows the view according to FIG. 4 in an alternative embodiment of the invention;

FIG. 8: shows an alternative embodiment of a handling system according to the invention;

FIG. 9: shows a component of the handling system from FIG. 8;

FIG. 10: shows a schematic illustration of a processing system according to the invention; and

FIG. 11: shows an alternative embodiment of a processing system according to the invention.

### DETAILED DESCRIPTION

In general, microlithographic photomasks 17 are provided for use in a microlithographic projection exposure apparatus (not depicted here). In the microlithographic projection exposure apparatus, the photomask 17 is illuminated with deep ultraviolet radiation or extreme ultraviolet radiation (DUV radiation/EUV radiation) in order to image a structure formed on the photomask 17 onto the surface of a lithographic object in the form of a wafer. The wafer is coated with a photoresist that reacts to the EUV radiation. An inspection system is used to examine whether the photomask meets the requirements and is free from contamination. A processing system serves to post-process photomasks or correct errors in photomasks.

A handling system according to the invention serves to pick up microlithographic photomasks 17 within an inspection system or processing system, bring them into the correct alignment, and put them down again.

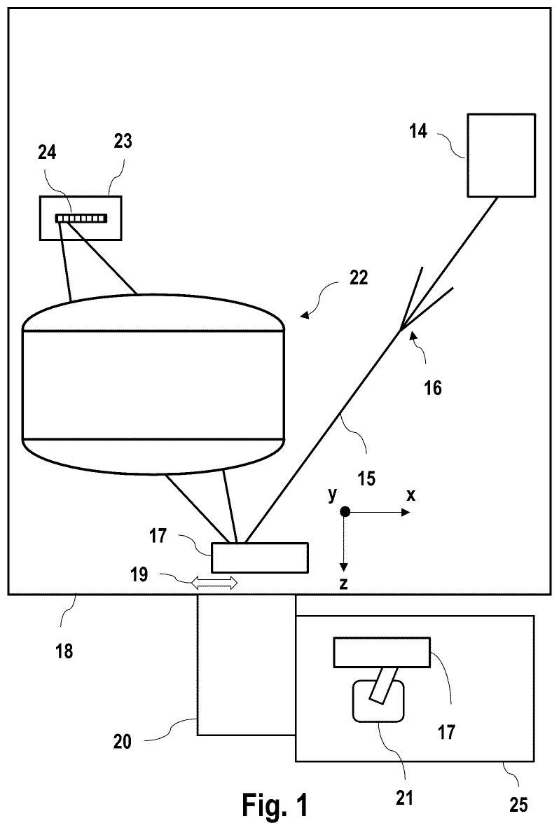

An exemplary embodiment of an inspection system is illustrated schematically in FIG. 1. The photomask 17 is arranged in the inspection system such that an EUV beam path 15 emanating from an EUV radiation source 14 is guided via an illumination system 16 to the photomask 17. The illumination system may comprise an illumination source for emitting EUV radiation. The illumination system may comprise a first mirror and a second mirror adapted to form a beam. The illumination system 16 is used to shape the EUV radiation to form a beam used to illuminate, with uniform brightness, an examination field on the surface of the photomask 17. The photomask 17 can have a rectangular shape with edge lengths of between 100 mm and 200 mm, for example. Using an XY-positioning mechanism 19, it is possible to move the photomask in the XY- plane in order to bring different examination fields of the photomask into the region of the EUV beam path.

The EUV beam path 15 reflected at the photomask 17 continues through a projection lens 22 to an EUV camera 23, which is equipped with an image sensor 24. The projection lens 22 is used to image the examination field of the photomask 17 on the image sensor 24 of the EUV camera 23. The EUV radiation source 14, the illumination system 16, the photomask 17, the projection lens 22 and the EUV camera 23 are arranged in a process chamber 18, in which negative pressure prevails during the operation of the measuring device.

The inspection system comprises a transfer lock 20, into which a photomask 17 to be examined is inserted at atmospheric pressure. The transfer lock 20 is brought to a vacuum corresponding to the vacuum chamber 18 before the photomask 17 is taken from the transfer lock 20.

The transfer of the photomask 17 to the transfer lock 20 is implemented by use of a handling system 21 arranged in an antechamber 25 of the inspection system. The handling system 21 is designed to bring the photomask 17 into the correct alignment. There are a total of eight possible alignments of the photomask 17, specifically a total of four positions that arise from a 90° rotation about a vertical axis 51 and four corresponding positions that arise after the photomask 17 was flipped through 180° about a horizontal axis 52. The photomask 17 can have any one of the eight possible alignments when inserted into the antechamber 25. Exactly one of the eight possible alignments is admissible for the examination in the inspection system.

The handling system 21 identifies the alignment of the photomask 17 in the antechamber 25 and, where necessary, brings the photomask 17 into the correct alignment by way of a suitable rotation about the vertical axis 51 (Z-axis) and by a flip about a horizontal axis 52. The photomask 17 is subsequently transferred to the process chamber 18 of the inspection system.

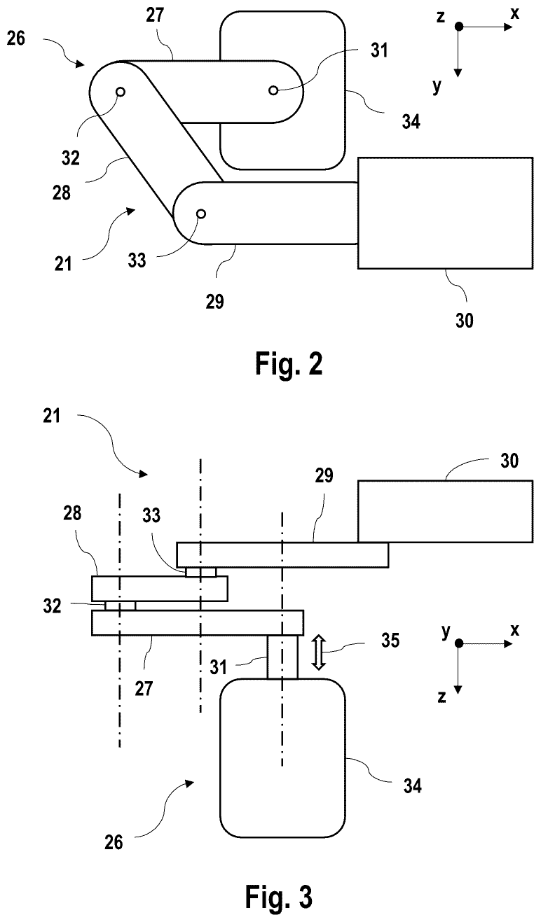

According to FIG. 2, the handling system 21 comprises an articulated arm robot 26 having a robot base 34, a first articulated arm 27, a second articulated arm 28 and a third articulated arm 29. The first articulated arm 27 is attached to the robot base 34 by way of a first revolute joint 31. The first revolute joint may comprise a first rotary drive, a first connector connected to the robot base 34 and a second connector connected to the first articulated arm 27. The second articulated arm 28 is attached to the first articulated arm 27 by way of a second revolute joint 32. The second revolute joint 32 may comprise a second rotary drive, a third connector connected to the first articulated arm 27 and a fourth connector connected to the second articulated arm 28. The third articulated arm 29 is attached to the second articulated arm 28 by way of a third revolute joint 33. The third revolute joint 33 may comprise a third rotary drive, a fifth connector connected to the second articulated arm 28 and a sixth connector connected to the third articulated arm 29. The third articulated arm 29 carries an alignment device 30. The axes of the revolute joints 31, 32, 33 are aligned perpendicularly—see FIG. 3—such that actuation of the revolute joints 31, 32, 33 allows the alignment device 30 carried by the third articulated arm 29 to be brought into different positions within the XY-plane. The articulated arm robot 26 also comprises a linear drive 35 which is formed between the robot base 34 and the first articulated arm 27 and which can be used to modify the height position of the alignment device 30.

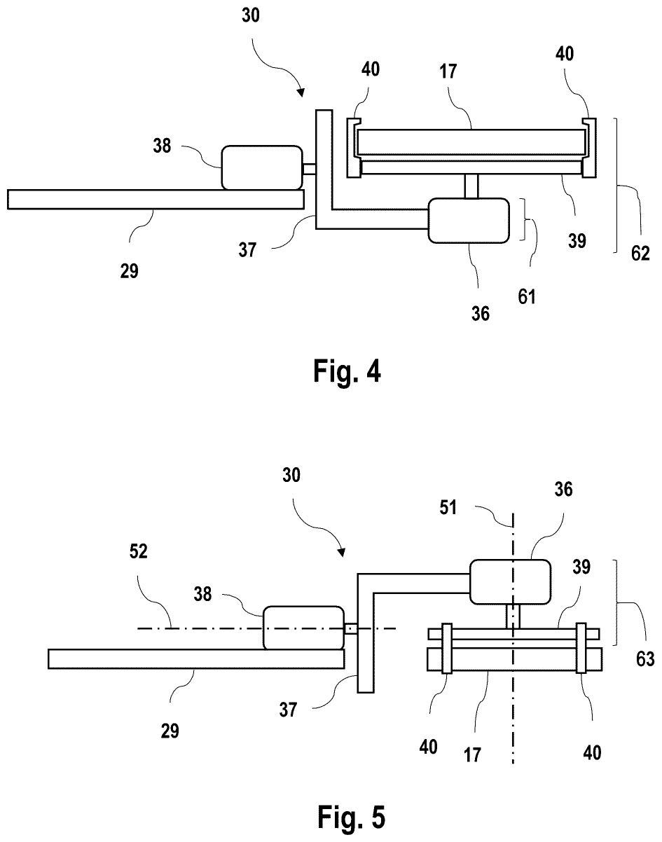

According to FIG. 4, the alignment device 30 comprises a holding mechanism 39 with two clamping jaws 40, between which the photomask 17 is held. The clamping jaws 40 can be made to approach one another by use of an actuator, for example in the form of a Lorentz actuator, in order to grip a photomask 17, or can be moved apart from one another in order to release a photomask 17. The holding mechanism 39 is attached to the third articulated arm 29 of the articulated arm robot 26 via a second rotary drive 38, a structure component 37 and a first rotary drive 36. The photomask 17 is rotated about a vertical axis by actuating the first rotary drive 36. The first rotary drive 36 can drive to four different angle positions which are separated by a rotary angle of 90° in each case.

The second rotary drive 38 can be used to flip the structure component 37, together with the first rotary drive 36 and the photomask 17, through 180° about a horizontal axis 52. By way of the two rotary positions of the second rotary drive 38 and the four rotary positions of the first rotary drive 36, the alignment device 30 provides a total of eight different alignments into which the photomask 17 can be brought. FIG. 5 shows one of the possible alignments, in which the photomask 17 has been flipped through 180° about the horizontal axis 52 and rotated through 90° about the vertical axis 51 in relation to the state in FIG. 4.

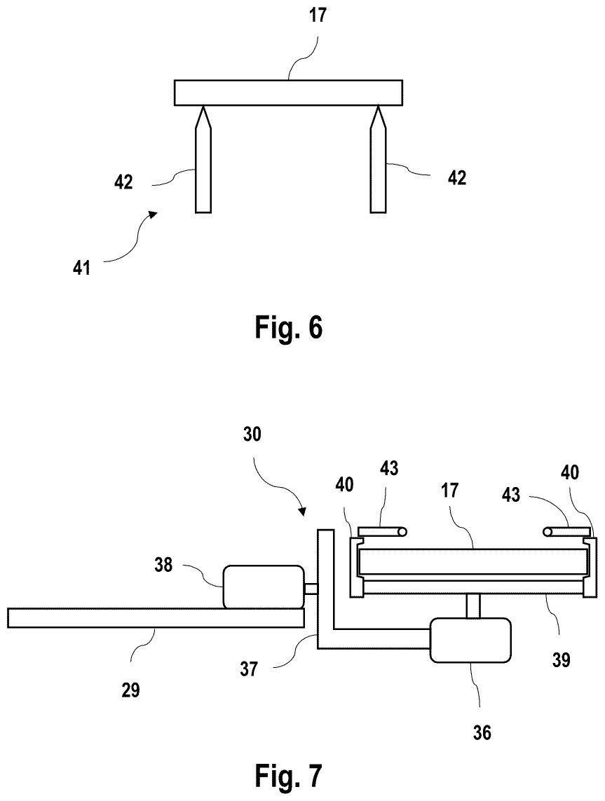

FIG. 6 shows a bearing station 41, on which the alignment device 30 can place the photomask 17 after the photomask 17 has been brought into the correct alignment. The bearing station 41 comprises bearing structures 42 which define punctiform regions on which the placed photomask 17 rests. In an alternative embodiment, the bearing station has inclined bearing faces, the distance from one another corresponding to the width of the photomask 17. The photomask rests with two opposite edges on the bearing faces of the bearing station. The edges of the photomask 17 can be provided with chamfers such that planar contact arises between the edges of the photomask and the bearing faces of the bearing station.

In the alternative exemplary embodiment in FIG. 7, the alignment device 30 comprises two sensor elements 43 that can be used to ascertain the current alignment of the photomask 17. The sensor elements 43 comprise optical sensors that respond to markers attached to the photomask 17. The measured values from the sensor elements 43 allow unambiguous determination of the alignment of the photomask 17 from the eight possible alignments. The photomask 17 can thus be transferred to the alignment device 30 in any alignment without the alignment device 30 requiring further information to proceed.

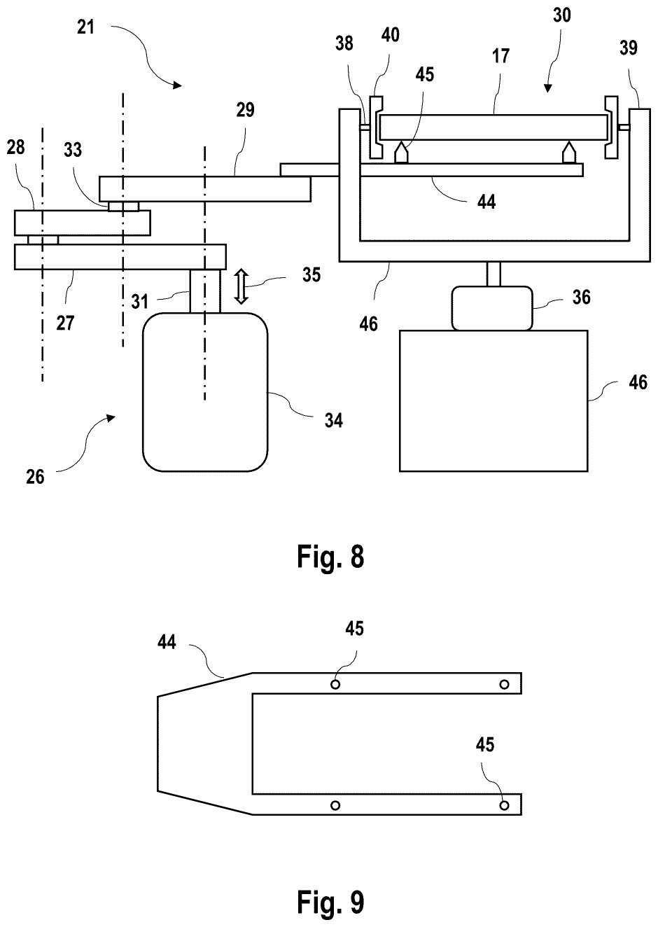

FIG. 8 shows an exemplary embodiment in which the alignment device 30 is a separate device from the articulated arm robot 26. The alignment device 30 is on the floor via a housing 46. The clamping jaws 40 are used to hold the photomask 17 on a frame bracket 39 that is attached to the housing 46 via a first rotary drive 36. A second rotary drive 38 that can be used to flip the photomask 17 through 180° about a horizontal axis is formed between the clamping jaws 40 and the frame bracket 39. The frame bracket 39, together with the photomask 17 is turned about a vertical axis by actuating the first rotary drive 36. The first rotary drive 36 is designed to drive to four positions which each differ by 90° from one another. Thus the alignment device 30 makes eight different alignments available, into which the photomask 17 can be brought.

As end effector, the articulated arm robot 26 comprises a receiving fork 44 (FIG. 9) which is attached to the third articulated arm 29 of the articulated arm robot 26. Upwardly directed bearing projections 45 are attached to the receiving fork 44. To take a photomask 17 from a bearing station 41, the third articulated arm 29 of the articulated arm robot 26 is displaced until the bearing projections 45 are arranged below the photomask 17. The linear drive 35 is used to lift the photomask 17 from the bearing station 41. The receiving fork 44 is displaced into the position shown in FIG. 8, in which the receiving fork 44 is arranged between two struts of the frame bracket 39 of the alignment device 30 and in which the photomask 17 is positioned between the clamping jaws 40 of the holding mechanism 30. The clamping jaws 40 are displaced such that the photomask 17 is held between the clamping jaws. The articulated arm robot 26 withdraws the receiving fork 44 such that the alignment device 30 can be actuated without colliding with parts of the articulated arm robot 26.

The photomask 17 is brought into the correct alignment by actuating the first rotary drive 36 and second rotary drive 38. Subsequently, the photomask 17 is taken from the alignment device 30 using a corresponding process and transferred to the next bearing station 41 of the inspection system. The photomask 17 now has the correct alignment for being examined in the process chamber of the inspection system.

As shown in FIG. 8, the frame bracket 39 of the alignment device 30 is designed such that space is available in each alignment of the photomask 17, into which space the receiving fork 44 can be driven from the side such that the receiving fork 44 assumes a position below the photomask 17.

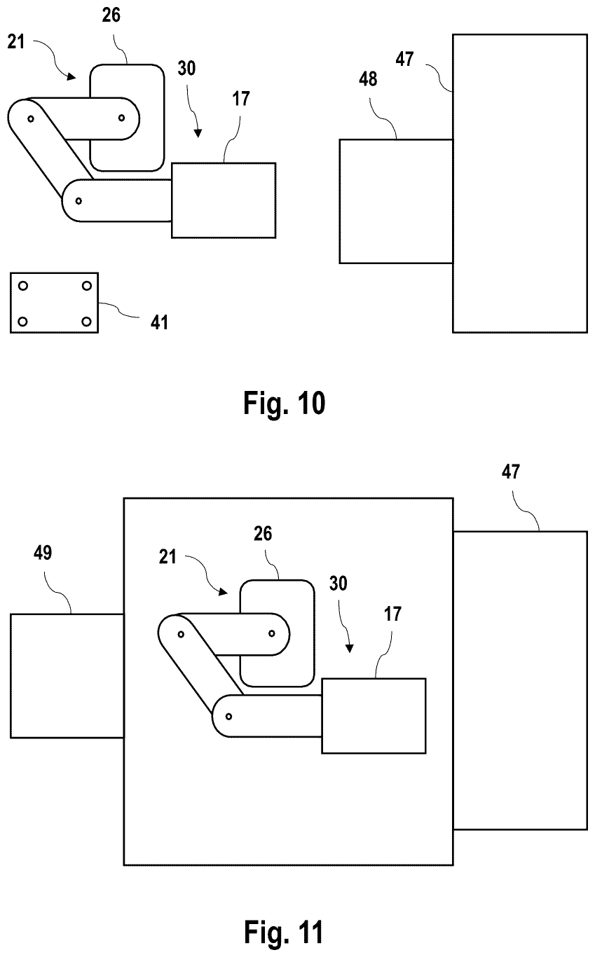

FIG. 10 schematically shows a process chamber 47 of a processing system for the DUV photomasks. An electron beam used to write specific structures into the substrate of the photomask is used to treat the photomasks in the process chamber 47.

The photomask 17 to be processed is made available by way of a bearing station 41. The handling system 21 lifts the photomask 17 from the bearing station 41. The alignment device 30 is used to bring the photomask 17 into the correct alignment, and said photomask is subsequently transferred into an antechamber 48 of the process chamber 47 by actuation of the articulated arm robot 26. Transfer into the process chamber 47 can be effected from the antechamber 48.

In the processing system in FIG. 11, the handling system 21 is arranged between a lock chamber 49 and the process chamber 47. The handling system 21 is designed to transfer the photomask 17 directly into the process chamber 47.

Each actuator of the handling system according to the invention has exactly one degree of freedom in all exemplary embodiments. As a result, the actuators can be encapsulated well, and so outgassing is prevented, even under the vacuum conditions under which the handling system is operated.

In some implementations, one or more computing devices can be configured to analyze sensor data and generate instructions to the control unit of the handling system. For example, the one or more computing devices can be configured to receive the measured values from the sensor elements 43, determine the current alignment of the photomask 17, and determine what rotation(s) about the vertical axis and/or horizontal axis is/are required to place the photomask 17 in the correct orientation. The one or more computing devices can be configured to instruct the control unit(s) of the handling system to generate control commands used to appropriately control the first rotary drive and/or the second rotary drive to rotate and/or flip the photomask 17 to the correct orientation. The one or more computing devices can be configured to instruct the control unit(s) of the handling system to generate control commands used to appropriately control one or more of the joint drives to move the photomask 17 along the XY-plane.

The one or more computing devices can include one or more data processors for processing data, one or more storage devices for storing data, and/or one or more computer programs including instructions that when executed by the one or more computing devices cause the one or more computing devices to carry out the method steps or processing steps. The one or more computing devices can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computing devices can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein. A number of embodiments of the invention have been described. Nevertheless, it will be understood that various modifications may be made without departing from the spirit and scope of the invention. Accordingly, other embodiments are within the scope of the following claims.

What is claimed is:

1. A handling system for microlithographic photomasks, having an articulated arm robot and having an alignment device, the alignment device being designed to rotate a photomask held by the alignment device about a vertical axis during a first movement process and flip said photomask about a horizontal axis during a second movement process.

2. The handling system according to claim 1, wherein the articulated arm robot comprises a robot base, a first articulated arm attached to the robot base by way of a first revolute joint, a second articulated arm attached to the first articulated arm by way of a second revolute joint and a third articulated arm attached to the second articulated arm by way of a third revolute joint.

3. The handling system according to claim 1, comprising a first rotary drive for rotating the photomask about the vertical axis, the first rotary drive having exactly one degree of freedom.

4. The handling system according to claim 3, wherein the first rotary drive has an axial extent of no more than 40 mm.

5. The handling system according to claim 3, wherein the first rotary drive is equipped with a vacuum-tight encapsulation.

6. The handling system according to claim 1, comprising a second rotary drive for rotating the photomask about the horizontal axis, the second rotary drive having exactly one degree of freedom.

7. The handling system according to claim 1, wherein the alignment device comprises a holding mechanism designed to hold the photomask independently of the alignment with respect to gravity.

8. The handling system according to claim 7, wherein the holding mechanism comprises a frame bracket and wherein the greatest distance between a photomask held by the holding mechanism and the frame bracket is less than 6 mm.

9. The handling system according to claim 7, wherein the holding mechanism comprises a gripping element and wherein the gripping element protrudes beyond the photomask held by the holding mechanism by no more than 3 mm on a side facing away from the frame bracket.

10. The handling system according to claim 1, wherein the vertical axis centrally intersects a photomask held in the holding mechanism.

11. The handling system according to claim 6, wherein the horizontal axis is located in a plane spanned by a photomask held in the holding mechanism.

12. The handling system according to claim 1, comprising a sensor mechanism for sensing the alignment of the photomask.

13. The handling system according to claim 1, wherein the alignment device is designed such that a support structure can be displaced under the photomask from a lateral direction in each of eight possible alignments of the photomask.

14. An inspection system for microlithographic photomasks, comprising a handling system and a process chamber for conducting an examination of a photomask, the handling system being designed to transfer the photomask to the process chamber or to an antechamber of the process chamber and the handling system being designed according to claim 1.

15. A processing system for microlithographic photomasks, comprising a handling system and a process chamber for conducting a processing step on a photomask, the handling system being designed to transfer the photomask to the process chamber or to an antechamber of the process chamber and the handling system being designed according to claim 1.

16. The inspection system according to claim 14, wherein the articulated arm robot comprises a robot base, a first articulated arm attached to the robot base by way of a first revolute joint, a second articulated arm attached to the first articulated arm by way of a second revolute joint and a third articulated arm attached to the second articulated arm by way of a third revolute joint.

17. The inspection system according to claim 14, wherein the handling system comprises a first rotary drive for rotating the photomask about the vertical axis, the first rotary drive having exactly one degree of freedom.

18. The inspection system according to claim 14, wherein the handling system comprises a second rotary drive for rotating the photomask about the horizontal axis, the second rotary drive having exactly one degree of freedom.

19. The processing system according to claim 15, wherein the articulated arm robot comprises a robot base, a first articulated arm attached to the robot base by way of a first revolute joint, a second articulated arm attached to the first articulated arm by way of a second revolute joint and a third articulated arm attached to the second articulated arm by way of a third revolute joint.

20. The processing system according to claim 15, wherein the handling system comprises a first rotary drive for rotating the photomask about the vertical axis, the first rotary drive having exactly one degree of freedom.
